(19) United States
(12) Patent Application Publication
(10) Pub. No.: US 2026/0150569 A1
(43) Pub. Date: May 28, 2026

(54) DISPLAY DEVICE

(71) Applicant: LG Display Co., Ltd., Seoul (KR)

(72) Inventors: Junehwan KIM, Paju-si (KR); Kyungkook JANG, Paju-si (KR); Youngmin OH, Paju-si (KR)

(73) Assignee: LG Display Co., Ltd., Seoul (KR)

(21) Appl. No.: 19/289,740

(22) Filed: Aug. 4, 2025

(30) Foreign Application Priority Data
Nov. 25, 2024 (KR) 10-2024-0169420

(51) Int. Cl. H10K 59/80; H10K 59/122

(52) U.S. Cl. CPC H10K 59/8792; H10K 59/122

(57) ABSTRACT

A display device according to one or more examples includes a substrate, a display area, a non-display area outside the display area, a first electrode disposed on the substrate, a bank overlapping a periphery of an upper surface of the first electrode, an organic layer on the first electrode and the bank, and a second electrode on the organic layer, where the bank includes core materials and black-based dyes combined with the core materials.

### CROSS-REFERENCE TO RELATED APPLICATIONS

The present application claims the benefit of and priority to Korean Patent Application No. 10-2024-0169420, filed Nov. 25, 2024, the entire contents of which are incorporated herein by reference for all purposes.

### TECHNICAL FIELD

The present disclosure relates to a display device.

### DESCRIPTION OF RELATED ART

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the pixels.

The description of related art should not be considered prior art merely because it is mentioned in or associated with this section. The description of related art includes information that describes one or more aspects of the subject technology, and the description in this section does not limit the scope of the invention.

### SUMMARY

Embodiments of the present disclosure are directed to providing a display device in which no volatile additive reacts with a first electrode in a pin hole of the first electrode, thereby preventing the intensity of luminance of a display panel from being lowered.

Embodiments of the present disclosure are also directed to providing a display device with structural stability in applying a black bank.

Embodiments of the present disclosure are also directed to providing a display device in which a ratio of black dye in a bank can be high, thereby reducing surface reflection (or external light reflection).

Embodiments of the present disclosure are also directed to providing low-reflection and low-power display device in which it is possible to prevent surface reflection of external light.

Embodiments of the present disclosure are directed to providing a display device which can have improved flexibility by omitting a polarizing unit and can be applied to a foldable product in which a display area is folded.

Aspects of the present disclosure are not limited to the above-described aspects, and other technical aspects may be inferred from the following embodiments.

According to one embodiment, there is provided a display device including a substrate, a display area, a non-display area outside the display area, a first electrode disposed on the substrate, a bank overlapping a periphery of an upper surface of the first electrode; an organic layer on the first electrode and the bank; and a second electrode on the organic layer, in which the bank includes core materials and black-based dyes combined with the core materials.

According to another embodiment, there is provided a display device including a substrate, a display area including a plurality of sub-pixels, a non-display area outside the display area, a first electrode disposed in each of the sub-pixels on the substrate and including a first conductive layer, a second conductive layer on the first conductive layer, and a third conductive layer on the second conductive layer, a bank overlapping a periphery of an upper surface of the first electrode, an organic layer on the first electrode and the bank, and a second electrode on the organic layer, in which the third conductive layer includes a hole passing therethrough in a thickness direction, and the bank includes black-based dyes.

Detailed matters of other embodiments are included in the detailed description and accompanying drawings.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further features, advantages, and aspects are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 is a plan view of the display device according to one embodiment.

FIG. 2 is a cross-sectional view illustrating a bent state of the display panel according to FIG. 1.

FIG. 3 is a cross-sectional view along line A-A′ in FIG. 1.

FIG. 4 is a specific cross-sectional view of a light-emitting part of FIG. 3.

FIG. 5 is a specific cross-sectional view of a light-emitting part according to a modified example.

FIG. 6 is a cross-sectional view of a touch part according to FIG. 3.

FIG. 7 is an enlarged cross-sectional view of area Q1 in FIG. 3.

FIG. 8A is a graph illustrating the intensity of luminance loss of the display device in a first environment.

FIG. 8B is a graph illustrating the intensity of luminance loss of the display device in a second environment.

FIG. 9 is a cross-sectional view illustrating the effect by a bank according to one embodiment.

FIG. 10 is a cross-sectional view of a display device according to another embodiment.

FIG. 11 is a cross-sectional view of a display device according to still another embodiment.

FIG. 12 is a cross-sectional view of a display device according to yet another embodiment.

FIG. 13 is a perspective view of a display device according to still another embodiment.

FIG. 14 is a cross-sectional view along line B-B′ in FIG. 13.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Hereinafter, embodiments will be described with reference to the accompanying drawings.

The same reference numerals indicate the same components. In addition, in the drawings, thicknesses, proportions, and dimensions of components can be exaggerated for effective description of technical contents. Scales of components illustrated in the drawings differ from the actual scale for convenience of description, and thus are not limited to the scales illustrated in the drawings.

In the disclosure, when a first component (or an area, a layer, a portion, etc.) is described as “on,” “connected,” or “coupled to” a second component, it means that the first component may be directly connected/coupled to the second component or a third component may be disposed therebetween.

The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise. For example, an element may be one or more elements. An element may include a plurality of elements.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” etc. can be used to easily describe the correlation of one element(s) with another element(s) as shown in the drawings. The spatially relative terms should be understood as including different directions of elements in use or operation in addition to the directions shown in the drawings. For example, in case of turning the element shown in the drawing upside down, an element described as being disposed “below” or “beneath” another element may be disposed “above” another element. Accordingly, the exemplary term “below” may include both downward and upward directions.

When the term “comprise,” “have,” “include,” “contain,” “constitute,” “made of,” “formed of,” “composed of,” or the like is used with respect to one or more elements (e.g., layers, films, components, electrodes, structures, transistors, sections, members, parts, regions, areas, portions, features, numbers, steps, operations, and/or the like), one or more other elements may be added unless a term such as “only” or the like is used. The terms used in the present disclosure are merely used in order to describe particular example embodiments, and are not intended to limit the scope of the present disclosure. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Features of various embodiments of the present disclosure may be coupled or combined partially or entirely, various technological interworking and driving are made possible, and the embodiments may be implemented independently of each other or implemented together in an associated relationship.

Hereinafter, a display device of the present disclosure will be described with reference to the accompanying drawings and embodiments as follows.

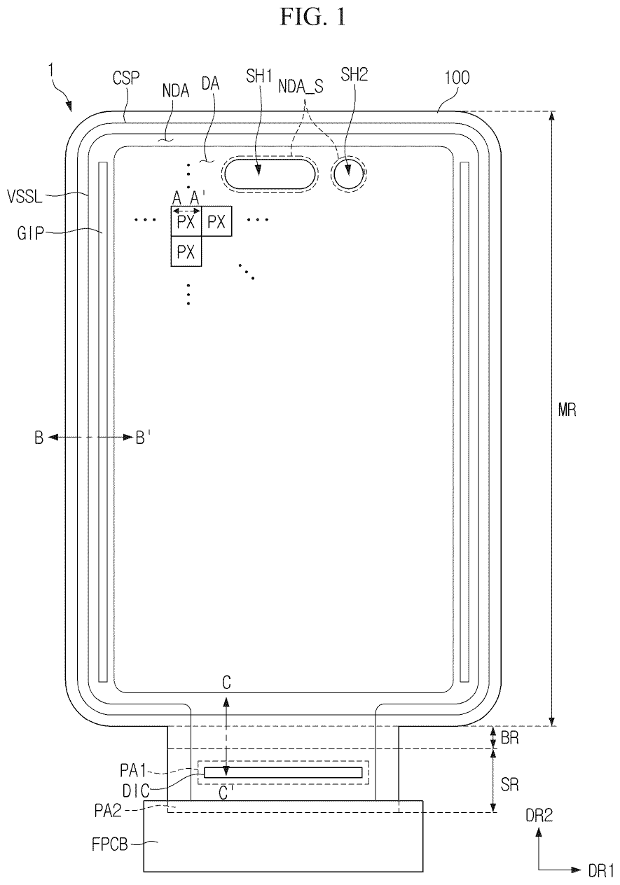

FIG. 1 is a plan view of the display device according to one embodiment.

Referring to FIG. 1, a display device 1 according to one embodiment may include a display panel 100. The display panel 100 may include a display area DA including a plurality of pixels PX and a non-display area NDA around the display area DA. The flat surface shape of the display area DA may have a rectangular shape. However, the embodiments of the present disclosure are not limited thereto, and the flat surface shape of the display area DA may be a square, circular, elliptical, or other polygonal shapes. For example, the display area DA may have a rectangular shape with rounded corners, but is not limited thereto and may also have a rectangular shape with angled corners.

In embodiments, a first direction DR1 and a second direction DR2 are different directions and intersect each other, for example, directions that intersect vertically in a plan view. In FIG. 1, the first direction DR1 may be generally the same as an extension direction of short sides of the display panel 100, and the second direction DR2 may be the same as an extension direction of long sides of the display panel 100. However, the directions described in the embodiments should be understood as indicating relative directions, and the embodiments are not limited to the described directions.

The display area DA may include short sides extending in the first direction DR1 and long sides extending in the second direction DR2. The non-display area NDA may surround the display area DA. The non-display area NDA may be disposed at one side and the other side of the display area DA in the first direction DR1 and one side and the other side of the display area DA in the second direction DR2.

The display panel 100 may further include a sensor non-display area NDA_S and a sensor hole SH1 and SH2 surrounded by the sensor non-display area NDA_S. The sensor hole SH1 and SH2 may be surrounded by the display area DA in a plan view. The sensor hole SH1 and SH2 may be, for example, two sensor holes as in FIG. 1, but the embodiments of the present disclosure are not limited thereto. For example, the sensor hole may be provided as one sensor hole. The two sensor holes SH1 and SH2 may respectively include a sensor hole in which an infrared sensor is disposed and a sensor hole in which a camera sensor is disposed, but the embodiments of the present disclosure are not limited thereto. The sensor non-display area NDA_S may be disposed between the sensor holes SH1 and SH2 and the display area DA. The sensor non-display area NDA_S may completely surround the sensor holes SH1 and SH2. A pixel PX may not be disposed in the sensor non-display area NDA_S.

A gate driving unit GIP may be disposed in the non-display area NDA located at one side and the other side of the display area DA in the first direction DR1. A low-potential voltage line VSSL may be disposed outside the gate driving unit GIP on the non-display area NDA. For example, as illustrated in FIG. 1, the low-potential voltage line VSSL may extend from a printed circuit board FPCB, pass a sub-region SR and a bending region BR, may be located outside the gate driving unit GIP on the non-display area NDA, and disposed to surround the display area DA.

The non-display area NDA located at the other side of the display area DA in the second direction DR2 may extend further from a central portion of the other side toward the other side of the display area DA in the second direction DR2. A width of the non-display area NDA in the first direction DR1 further extending from the central portion of the other side toward the other side of the display area DA in the second direction DR2 may be smaller than a width of the non-display area NDA in the first direction DR1 adjacent to the other side of the display area DA in the second direction DR2.

The display device 1 may include a main region MR, the sub-region SR, and the bending region BR between the main region MR and the sub-region SR. The display area DA and the non-display area NDA surrounding four surfaces of the display area DA may form the main region MR, and a portion extending from the central portion of the other side toward the other side of the display area DA in the second direction DR2 may form the bending region BR and the sub-region SR. The bending region BR may be disposed between the sub-region SR and the main region MR. The sub-region SR may include a first pad area PA1 and a second pad area PA2 located at an end portion of the other side of the sub-region SR in the second direction DR2. The display device 1 may further include a data driving unit DIC and a printed circuit board FPCB. The data driving unit DIC may be disposed in the first pad area PA1, and the printed circuit board FPCB may be attached to the second pad area PA2. A plurality of pads connected to the data driving unit DIC and the printed circuit board FPCB may be disposed in each of the first pad area PA1 and the second pad area PA2. The data driving unit DIC may be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but the embodiments of the present disclosure are not limited thereto, and the data driving unit DIC may be disposed by a chip on glass or chip on film method.

The display panel 100 according to one embodiment may further include a crack sensing pattern CSP surrounding the low-potential voltage line VSSL. The crack sensing pattern CSP may be disposed to completely surround the display area DA as illustrated in FIG. 1. For example, the crack sensing pattern CSP may be disposed outside the low-potential voltage line VSSL. However, the embodiments of the present disclosure are not limited thereto, and the crack sensing pattern CSP may not be disposed in the non-display area NDA at the other side of the display area DA in the second direction DR2.

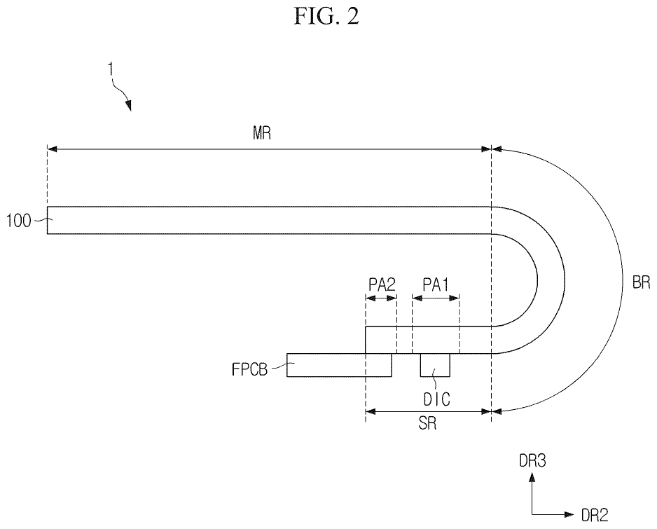

FIG. 2 is a cross-sectional view illustrating a bent state of the display panel according to FIG. 1.

Referring to FIG. 2, the bending region BR of the display panel 100 of the display device 1 according to one embodiment may be bent in a thickness direction (or a third direction DR3). Accordingly, the main region MR and the sub-region SR may overlap each other in the thickness direction. The display panel 100 may be bent in such a manner that a lower surface of the main region MR faces an upper surface of the sub-region SR. The printed circuit board FPCB may be attached to an end portion of the sub-region SR.

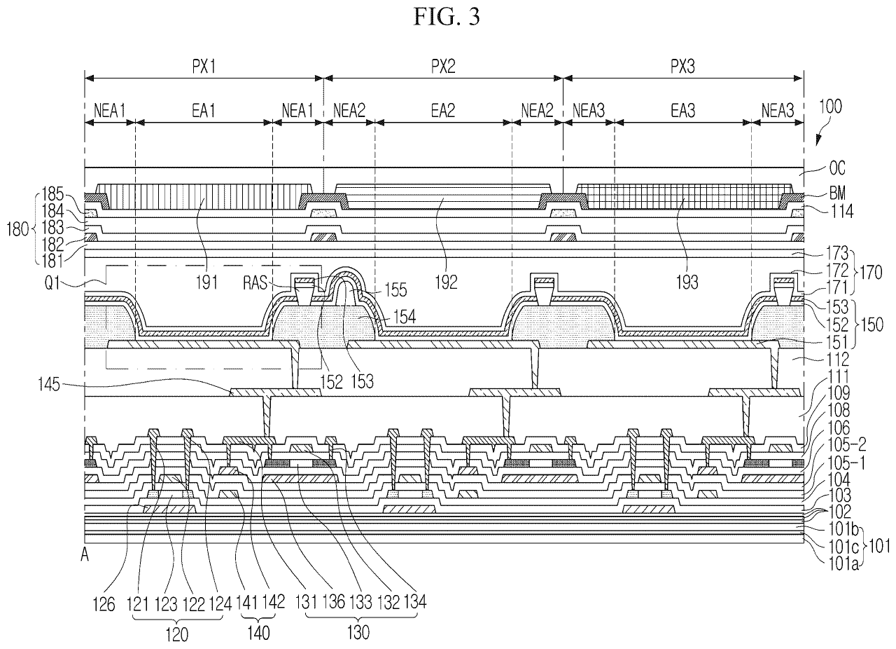

FIG. 3 is a cross-sectional view along line A-A′ in FIG. 1.

Referring to FIG. 3, the pixel PX (see FIG. 1) of the display panel 100 may include a plurality of sub-pixels PX1, PX2, and PX3. A first sub-pixel PX1 may be a red sub-pixel, a second sub-pixel PX2 may be a green sub-pixel, and a third sub pixel PX3 may be a blue sub-pixel, but the embodiments of the present disclosure are not limited thereto. In some embodiments, the pixel PX further includes a fourth sub-pixel, and the fourth sub-pixel may be a white sub-pixel, but the embodiments of the present disclosure are not limited thereto. In some embodiments, the pixel may include one red sub-pixel, two green sub-pixels, and one blue sub-pixel, but the embodiments of the present disclosure are not limited thereto. For example, the plurality of sub-pixels PX1, PX2, and PX3 may be arranged in a stripe manner in the first direction DR1, but are not limited thereto, and may be arranged in a pentile manner.

The display panel 100 may include a substrate 101, a first thin film transistor 120, a second thin film transistor 130, a light-emitting part 150, an encapsulation part 170, a touch part 180, a filter insulating layer 114, a black matrix BM, color filters 191, 192, and 193, and a planarization layer OC. The display panel 100 may include at least one panel insulating layer and at least one touch insulating layer between the substrate 101 and the light-emitting part 150. The at least one panel insulating layer may include at least one of a buffer layer 102, a first insulating layer 103, a second insulating layer 104, a 3-1 insulating layer 105-1, a 3-2 insulating layer 105-2, a fourth insulating layer 106, a fifth insulating layer 108, a sixth insulating layer 109, a first protective layer 111, and a second protective layer 112, and the at least one touch insulating layer may include at least one of a touch buffer layer 181, a first touch insulating layer 183, and a second touch insulating layer 184.

The substrate 101 may include one or more plastic materials. For example, the substrate 101 may be a multi-layer substrate including a plurality of plastic materials, such as polyimide, etc. For example, the substrate 101 may include a first substrate portion 101a and a second substrate portion 101b each including a plastic material, and a third substrate portion 101c including an inorganic insulation material between the first substrate portion 101a and the second substrate portion 101b, but the embodiments of the present disclosure are not limited thereto.

The buffer layer 102 may be disposed on the substrate 101. The buffer layer 102 can minimize or delay the diffusion of moisture or oxygen into the substrate 101. The buffer layer 102 may be formed by alternately stacking silicon nitride (SiNₓ) and silicon oxide (SiOₓ) at least once, but the embodiments of the present disclosure are not limited thereto.

A first light-blocking layer 126 may be disposed on the buffer layer 102. The first light-blocking layer 126 can prevent light from transmitting a first semiconductor layer 123 of the first thin film transistor 120. For example, the first semiconductor layer 123 may be disposed to overlap the first light-blocking layer 126. The first light-blocking layer 126 may be formed of a single layer or multiple layers formed of one of molybdenum (Mo), aluminum (Al), chromium (Cr), nickel (Ni), neodymium (Nd), and copper (Cu) or an alloy thereof, but the embodiments of the present disclosure are not limited thereto.

The first insulating layer 103 may be disposed on the buffer layer 102 and the first light-blocking layer 126. The first insulating layer 103 can prevent a short circuit between a component of the first thin film transistor 120 and the first light-blocking layer 126. The first insulating layer 103 may be formed of the same material as the buffer layer 102, but the embodiments of the present disclosure are not limited thereto. For example, the first insulating layer 103 may be formed of an inorganic insulation material, such as silicon nitride (SiNₓ) or silicon oxide (SiOₓ), but the embodiments of the present disclosure are not limited thereto.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto. The first semiconductor layer 123 may include a channel area, a source area, and a drain area.

Since the polycrystalline semiconductor layer has higher mobility than the amorphous semiconductor layer and the oxide semiconductor layer, power consumption can be less, and reliability can be excellent. Accordingly, a driving transistor may be formed of the polycrystalline semiconductor layer.

The second insulating layer 104 may be disposed on the first semiconductor layer 123. The second insulating layer 104 may be formed of the same material as the first insulating layer 103 and can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto. The first gate electrode 122 may be disposed along with a gate line.

Third insulating layers 105-1 and 105-2 may be disposed on the first gate electrode 122. The third insulating layers 105-1 and 105-2 may be formed by alternately stacking silicon nitride (SiNₓ) and silicon oxide (SiOₓ) at least once, but the embodiments of the present disclosure are not limited thereto. For example, a 3-1 insulating layer 105-1 may include silicon oxide (SiOₓ), and a 3-2 insulating layer 105-2 may include silicon nitride (SiNₓ), but the embodiments of the present disclosure are not limited thereto.

The first source electrode 121 and the first drain electrode 124 may be disposed on the third insulating layers 105-1 and 105-2.

The first source electrode 121 and the first drain electrode 124 may be electrically connected to the first semiconductor layer 123 through contact holes. The first source electrode 121 and the first drain electrode 124 may include a metallic material. For example, the first source electrode 121 and the first drain electrode 124 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The first source electrode 121 and the first drain electrode 124 may be disposed along with a data line. For example, the data line may be made of the same material as the first source electrode 121 and the first drain electrode 124 and may be formed coplanarly therewith, but the embodiments of the present disclosure are not limited thereto.

A storage electrode 140 may be disposed to be spaced apart from the first thin film transistor 120. The storage electrode 140 may include a first storage electrode 141 and a second storage electrode 142.

The first storage electrode 141 may be formed of the same material as the first gate electrode 122 and disposed on the same layer as the first gate electrode 122, but the embodiments of the present disclosure are not limited thereto.

The second storage electrode 142 may be disposed on the first storage electrode 141. The second storage electrode 142 may be disposed on the third insulating layers 105-1 and 105-2, and the third insulating layers 105-1 and 105-2 between the first storage electrode 141 and the second storage electrode 142 may be used as a dielectric to generate a capacitance. The second storage electrode 142 may be formed of the same material as the first storage electrode 141, but the embodiments of the present disclosure are not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-blocking layer 136 may be disposed on the same layer as the second storage electrode 142.

The second light-blocking layer 136 can prevent light from traveling to the second semiconductor layer 133 similar to the first light-blocking layer 126, thereby extending the life of the second thin film transistor 130. For example, the second semiconductor layer 133 may be disposed to overlap the second light-blocking layer 136.

A fourth insulating layer 106 may be disposed on the second light-blocking layer 136. The fourth insulating layer 106 may be formed of the same material as the first insulating layer 103, the second insulating layer 104, or the third insulating layers 105-1 and 105-2, but the embodiments of the present disclosure are not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present disclosure are not limited thereto.

A fifth insulating layer 108 may be disposed on the second semiconductor layer 133. The fifth insulating layer 108 may be formed of the same material as the first insulating layer 103, the second insulating layer 104, the third insulating layers 105-1 and 105-2, or the fourth insulating layer 106, but the embodiments of the present disclosure are not limited thereto.

The second gate electrode 132 may be disposed on the fifth insulating layer 108.

The second gate electrode 132 may be formed of the same material as the first gate electrode 122. For example, the second gate electrode 132 may be formed of a single layer or multiple layers formed of molybdenum (Mo), copper (Cu), titanium (Ti), aluminum (Al), chromium (Cr), gold (Au), nickel (Ni), neodymium (Nd), or a compound thereof, but the embodiments of the present disclosure are not limited thereto.

A sixth insulating layer 109 may be disposed on the second gate electrode 132. The sixth insulating layer 109 may be formed of the same material as the first insulating layer 103, the second insulating layer 104, the third insulating layers 105-1 and 105-2, the fourth insulating layer 106, or the fifth insulating layer 108, but the embodiments of the present disclosure are not limited thereto.

The first source electrode 121, the first drain electrode 124, the second source electrode 131, and the second drain electrode 134 may be disposed on the sixth insulating layer 109.

The second source electrode 131 and the second drain electrode 134 may be formed of the same material as the first source electrode 121 and the first drain electrode 124 and disposed on the same layer as the first source electrode 121 and the first drain electrode 124, but the embodiments of the present disclosure are not limited thereto. For example, the second source electrode 131 and the second drain electrode 134 may be formed of a single layer or multiple layers formed of any one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto. For example, the second source electrode 131 may be electrically connected to the second storage electrode 142. The second source electrode 131 may pass through the sixth insulating layer 109, the fifth insulating layer 108, and the fourth insulating layer 106 and may be electrically connected to the second storage electrode 142.

The first thin film transistor 120 may be a driving transistor, and the second thin film transistor 130 may be a switching transistor, but the embodiments of the present disclosure are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be formed of an organic material. For example, the first protective layer 111 may be formed of an organic material including an acrylic resin, an epoxy resin, a phenolic resin, a polyamide resin, or a polyimide resin, but the embodiments of the present disclosure are not limited thereto.

The second protective layer 112 may be disposed on the first protective layer 111. The second protective layer 112 may include the same material as the first protective layer 111, but the embodiments of the present disclosure are not limited thereto.

In some embodiments, a third protective layer may be further disposed on an upper surface of the second protective layer 112, but the embodiments of the present disclosure are not limited thereto.

A connection electrode 145 may be disposed between the first protective layer 111 and the second protective layer 112.

The connection electrode 145 may electrically connect the first thin film transistor 120 to the light-emitting part 150. The connection electrode 145 may be formed of the same material as the first source electrode 121 and the first drain electrode 124, but the embodiments of the present disclosure are not limited thereto.

The connection electrode 145 may be formed of a single layer or multiple layers formed of one of molybdenum (Mo), aluminum (Al), chromium (Cr), gold (Au), titanium (Ti), nickel (Ni), neodymium (Nd), and copper (Cu) or an alloy thereof, but the embodiments of the present disclosure are not limited thereto.

The light-emitting part 150 may be disposed on the second protective layer 112. The light-emitting part 150 may include a first electrode 151, an organic layer 152, and a second electrode 153. The first electrode 151 may serve as an anode, and the second electrode 153 may serve as a cathode.

The first electrode 151 may be disposed on the second protective layer 112. The first electrode 151 may be electrically connected to the first thin film transistor 120 through a contact hole formed in the second protective layer 112. The first electrode 151 may be a reflective electrode that reflects light, but the embodiments of the present disclosure are not limited thereto. The first electrode 151 may include a metallic material with high reflectance, such as a stacked structure (Ti/Al/Ti) of aluminum (Al) and titanium (Ti), a stacked structure (ITO/Al/ITO) of aluminum (Al) and indium tin oxide (ITO), or an APC alloy and may be formed of a single layer or multiple layers, but the embodiments of the present disclosure are not limited thereto.

The organic layer 152 may be disposed on the first electrode 151. The organic layer 152 may include one or more light-emitting structures (or light-emitting elements) stacked on the first electrode 151 in the order or reverse order of a hole transfer layer and an electron transfer layer. For example, the hole transfer layer may include a hole transporting layer, a hole injecting layer, an electron blocking layer, a p-type charge generation layer, etc., but the embodiments of the present disclosure are not limited thereto. For example, the electron transfer layer may include an electron transporting layer, an electron injecting layer, a hole blocking layer, an n-type charge generation layer, etc., but the embodiments of the present disclosure are not limited thereto. The organic layer 152 may be an organic light-emitting layer, an inorganic light-emitting layer, a quantum dot light-emitting layer, a micro light-emitting diode, a mini light-emitting diode, etc., but the embodiments of the present disclosure area not limited thereto. For example, the organic layer 152 of the display panel 100 according to one embodiment of the present disclosure may include an organic light-emitting layer. The organic layer 152 may include a red light-emitting layer, a green light-emitting layer, and a blue light-emitting layer. The organic layer 152 may further include a white light-emitting layer, but the embodiments of the present disclosure are not limited thereto. Hereinafter, a specific structure of the organic layer 152 according to one embodiment will be described.

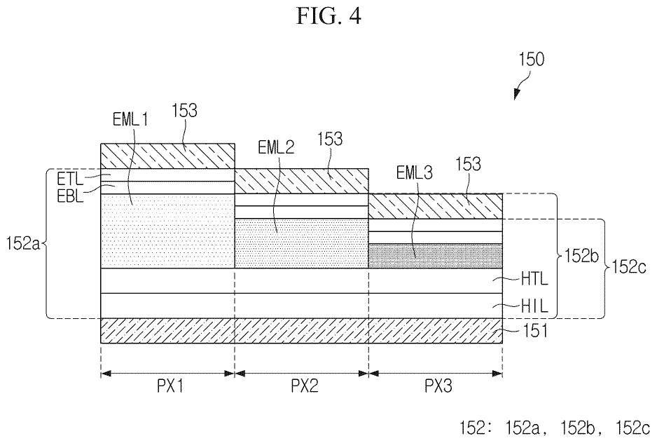

FIG. 4 is a specific cross-sectional view of a light-emitting part of FIG. 3.

Referring to FIG. 4, the light-emitting part 150 may include the first sub-pixel PX1, the second sub-pixel PX2, and the third sub-pixel PX3.

A thickness of the light-emitting part 150 in each sub-pixel PX1, PX2, or PX3 may be different, but the embodiments of the present disclosure are not limited thereto, and the thickness of the light-emitting part 150 in each sub-pixel PX1, PX2, or PX3 may be the same.

The organic layer 152 may include a first organic layer 152a disposed in the first sub-pixel PX1, a second organic layer 152b disposed in the second sub-pixel PX2, and a third organic layer 152c disposed in the third sub-pixel PX3. Light-emitting layers EML1, EML2, and EML3 of the organic layers 152a, 152b, and 152c may be physically separated, but lower layers and upper layers of the light-emitting layers EML1, EML2, and EML3 may be formed integrally across the sub-pixels PX1, PX2, and PX3. A thicknesses of each light-emitting layer EML1, EML2, or EML3 may be different. For example, a thickness of a first light-emitting layer EML1 may be the greatest, a thickness of a second light-emitting layer EML2 may be the second greatest, and a thickness of the third light-emitting layer EML3 may be the smallest, but the embodiments of the present disclosure are not limited thereto.

A hole injecting layer HIL may be disposed on the first electrode 151. The hole injecting layer HIL may be located between the first electrode 151 and the light-emitting layers EML1, EML2, and EML3. The hole injecting layer HIL may be disposed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A hole transporting layer HTL may be disposed on the hole injecting layer HIL. The hole transporting layer HTL may be located between the hole injecting layer HIL and the light-emitting layers EML1, EML2, and EML3. The hole transporting layer HTL may be disposed integrally across the sub-pixels PX1, PX2, and PX3. The hole transporting layer HTL may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″Tris(N-3-methylphenyl-N-phenyl-amino)-triphenylamine), but the embodiments of the present disclosure are not limited thereto.

The light-emitting layers EML1, EML2, and EML3 may be disposed on the hole transporting layer HTL. The first light-emitting layer EML1 may be disposed in the first sub-pixel PX1, the second light-emitting layer EML2 may be disposed in the second sub-pixel PX2, and the third light-emitting layer EML3 may be disposed in the third sub-pixel PX3.

A thicknesses of each light-emitting layer EML1, EML2, or EML3 may be different. For example, the first light-emitting layer EML1 may be formed in a thickness of 60 to 80 nm, the second light-emitting layer EML2 may be formed in a thickness of 30 to 50 nm, and the third light-emitting layer EML3 may be formed in a thickness of 10 to 30 nm, but the embodiments of the present disclosure are not limited thereto.

Each of the first light-emitting layer EML1, the second light-emitting layer EML2, and the third light-emitting layer EML3 may include a material that may emit light in the visible light range by receiving and combining holes and electrons.

An electron blocking layer EBL may be disposed on each light-emitting layer EML1, EML2, or EML3. The electron blocking layer EBL may be disposed integrally across the sub-pixels PX1, PX2, and PX3.

An electron transporting layer ETL may be disposed on the electron blocking layer EBL. The electron transporting layer ETL may be disposed integrally across the sub-pixels PX1, PX2, and PX3. The electron transporting layer ETL may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The second electrode 153 may be disposed on the electron transporting layer ETL.

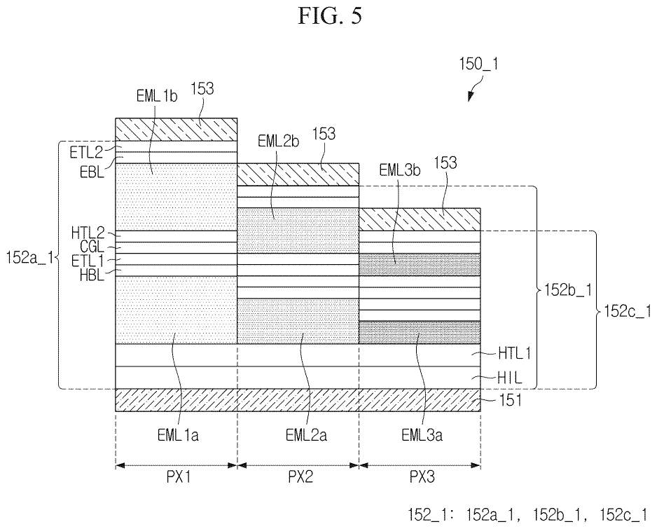

FIG. 5 is a specific cross-sectional view of a light-emitting part according to a modified example.

Referring to FIGS. 4 and 5, an organic layer 152_1 may include a first organic layer 152a_1 disposed in the first sub-pixel PX1, a second organic layer 152b_1 disposed in the second sub-pixel PX2, and a third organic layer 152c_1 disposed in the third sub-pixel PX3.

As illustrated in FIGS. 4 and 5, an example in which the light-emitting layer is formed in 1 stack or 2 stacks of the organic layers 152 and 152_1 for each sub-pixel PX1, PX2, or PX3 is illustrated, but the embodiments of the present disclosure are not limited thereto, and the light-emitting layer may be formed in 3 or more stacks.

The light-emitting layers of each organic layer 152a_1, 152b_1, or 152c_1 may be physically separated, but the lower layers and upper layers of the light-emitting layers may be disposed integrally across the sub-pixels PX1, PX2, and PX3. The thickness of each light-emitting layer may be different. For example, the thickness of the first light-emitting layer of the first sub-pixel may be the greatest, the thickness of the second light-emitting layer of the second sub-pixel may be the second greatest, and the thickness of the third light-emitting layer of the third sub-pixel may be the smallest, but the embodiments of the present disclosure are not limited thereto. In addition, the light-emitting layers of each organic layer 152a_1, 152b_1, or 152c_1 may be provided as two or more light-emitting layers.

A hole injecting layer HIL may be disposed on the first electrode 151. The hole injecting layer HIL may be located between the first electrode 151 and the light-emitting layers EML1a, EML2a, and EML3a. The hole injecting layer HIL may be disposed integrally across the sub-pixels PX1, PX2, and PX3. For example, the hole injecting layer HIL may be formed of a hole injecting material that is one selected from MTDATA, CuPc, TCTA, NPB (NPD), HATCN, TDAPB, PEDOT/PSS, F4TCNQ, N-(biphenyl-4-yl)-9,9-dimethyl-N-(4-(9-phenyl-9H-carbazol-3-yl)phenyl)-9H-fluoren-2-amine, etc., but the embodiments of the present disclosure are not limited thereto.

A first hole transporting layer HTL1 may be disposed on the hole injecting layer HIL. The first hole transporting layer HTL1 may be located between the hole injecting layer HIL and light-emitting layers EML1a, EML2a, and EML3a. The first hole transporting layer HTL1 may be disposed integrally across the sub-pixels PX1, PX2, and PX3. The first hole transporting layer HTL1 may be formed of one or more selected from the group consisting of arylamine-based materials, such as NPB (N,N-naphthyl-N,N′-phenyl benzidine), TPD (N,N′-bis-(3-methylphenyl)-N,N′-bis-(phenyl)-benzidine), PPD, TTBND, FFD, p-dmDPS, and TAPC, starbust aromatic amine-based materials, such as TCTA, PTDATA, TDAPB, TDBA, 4-a, and TCTA, and spiro and ladder type materials, such as Spiro-TPD, Spiro-mTTB, and Spiro-2, NPD (N,N-dinaphthylN,N′-diphenyl benzidine), s-TAD, and MTDATA(4,4′,4″-Tris(N-3-methylphenyl-N-phenyl-amino)-triphenylamine), but the embodiments of the present disclosure are not limited thereto.

The light-emitting layers EML1a, EML2a, and EML3a may be disposed on the first hole transporting layer HTL1. A 1-1 light-emitting layer EML1a may be disposed in the first sub-pixel PX1, a 2-1 light-emitting layer EML2a may be disposed in the second sub-pixel PX2, and a 3-1 light-emitting layer EML3a may be disposed in the third sub-pixel PX3. Each of the light-emitting layers EML1a, EML2a, and EML3a may be the same as each of the light-emitting layers EML1, EML2, and EML3 of FIG. 4.

A thicknesses of each light-emitting layer EML1a, EML2a, or EML3a may be different. For example, the 1-1 light-emitting layer EML1a may be formed in a thickness of 60 to 80 nm, the 2-1 light-emitting layer EML2a may be formed in a thickness of 30 to 50 nm, and the 3-1 light-emitting layer EML3a may be formed in a thickness of 10 to 30 nm, but the embodiments of the present disclosure are not limited thereto.

A hole blocking layer HBL may be disposed on each light-emitting layer EML1a, EML2a, or EML3a. The hole blocking layer HBL may be disposed integrally across the sub-pixels PX1, PX2, and PX3.

A first electron transporting layer ETL1 may be disposed on the hole blocking layer HBL. The first electron transporting layer ETL1 may be formed integrally across the sub-pixels PX1, PX2, and PX3. The first electron transporting layer ETL1 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

A common charge layer CGL may be disposed on the first electron transporting layer ETL1. The common charge layer CGL may be disposed between the first electron transporting layer ETL1 and the second hole transporting layer HTL2. The common charge layer CGL may include a conductive material, but the embodiments of the present disclosure are not limited thereto.

The second hole transporting layer HTL2 may be disposed on the common charge layer CGL. The second hole transporting layer HTL2 may be disposed between the hole blocking layer HBL and the light-emitting layers EML1b, EML2b, and EBL3b. The second hole transporting layer HTL2 may be disposed integrally across the sub-pixels PX1, PX2, and PX3. A material of the second hole transporting layer HTL2 may be the same as a material of the first hole transporting layer HTL1, but the embodiments of the present disclosure are not limited thereto.

The light-emitting layers EML1b, EML2b, and EML3b may be disposed on the second hole transporting layer HTL2. A 1-2 light-emitting layer EML1b may be disposed in the first sub-pixel PX1, a 2-2 light-emitting layer EML2b may be disposed in the second sub-pixel PX2, and a 3-2 light-emitting layer EML3b may be disposed in the third sub-pixel PX3. Each of the light-emitting layers EML1b, EML2b, and EML3b may be the same as each of the light-emitting layers EML1a, EML2a, and EML3a.

A thicknesses of each light-emitting layer EML1b, EML2b, or EML3b may be different. For example, the 1-2 light-emitting layer EML1b may be formed in a thickness of 600 to 800 Å, the 2-2 light-emitting layer EML2b may be formed in a thickness of 300 to 500 Å, and the 3-2 light-emitting layer EML3b may be formed in a thickness of 100 to 300 Å, but the embodiments of the present disclosure are not limited thereto.

An electron blocking layer EBL may be disposed on each light-emitting layer EML1b, EML2b, or EML3b. The electron blocking layer EBL may be disposed integrally across the sub-pixels PX1, PX2, and PX3.

A second hole transporting layer ETL2 may be disposed on the electron blocking layer EBL. The second electron transporting layer ETL2 may be formed integrally across the sub-pixels PX1, PX2, and PX3. The second electron transporting layer ETL2 may be formed of an anthracene derivative and lithium quinolate (Liq) or formed of one or more selected from oxadiazole, triazole, phenanthroline, benzoxazole, benzthiazole, or benzimidazole (e.g., 2-[4-(9,10-Di-2-naphthalenyl-2-anthracenyl)phenyl]-1-phenyl-1H-benzimidazole), but the embodiments of the present disclosure are not limited thereto.

The second electrode 153 may be disposed on the second electron transporting layer ETL2.

Referring back to FIG. 3, the second electrode 153 may be disposed on the organic layer 152. The second electrode 153 may be a transparent electrode that transmits light, but the embodiments of the present disclosure are not limited thereto. For example, the second electrode 153 may include a transparent conductive material, such as indium tin oxide (ITO) or indium zinc oxide (IZO), or a metal that transmits visible light, but the embodiments of the present disclosure are not limited thereto.

A bank 154 may be disposed to expose the first electrode 151. The bank 154 may define openings (or light-emitting areas EA1, EA2, and EA3) of the sub-pixels PX1, PX2, and PX3 and may be disposed to cover an edge portion (or a periphery) of the first electrode 151. That is, the first sub-pixel PX1 may include a first light-emitting area EA1 and a first non-light-emitting area NEA1 around the first light-emitting area EA1, the second sub-pixel PX2 may include a second light-emitting area EA2 and a second non-light-emitting area NEA2 around the second light-emitting area EA2, and the third sub-pixel PX3 may include a third light-emitting area EA3 and a third non-light-emitting area NEA3 around the third light-emitting area EA3. That is, each non-light-emitting area NEA1, NEA2, or NEA3 may correspond to a boundary between adjacent sub-pixels PX1, PX2, and PX3.

The bank 154 may include a black-based material. For example, the bank 154 may be formed of a material containing black pigment, or an organic material, such as a benzocyclobutene resin, a polyimide resin, an acrylic resin, a photosensitive polymer, etc., but the embodiments of the present disclosure are not limited thereto. When the bank 154 is formed of a material containing black pigment or black dye, the bank 154 may be a black bank. When the bank 154 is formed of a material containing black pigment or black dye, it is possible to shield external light or light reflected from the outside, thereby preventing a reduction in the intensity of luminance of the display device.

A barrier RAS may be further disposed on the bank 154. As illustrated in FIG. 3, the barrier RAS may be disposed at all the boundaries NEA1, NEA2, and NEA3 between the sub-pixels PX1, PX2, and PX3, but the embodiments of the present disclosure are not limited thereto. The barrier RAS may be disposed directly on an upper surface of the bank 154, but the embodiments of the present disclosure are not limited thereto. The barrier RAS may serve to separate the organic layer 152 from the boundaries of adjacent sub-pixels PX1, PX2, and PX3. In some embodiments, the barrier RAS may be omitted, and a trench structure recessed from the surface of the bank 154 may be applied.

A spacer 155 may be further disposed on the bank 154. The spacer 155 may be formed of the same material as the bank 154, but the embodiments of the present disclosure are not limited thereto. For example, the spacer 155 may be a transparent bank, but is not limited thereto, and the spacer 155 may be formed of the same material as the bank 154. For example, the spacer 155 may be disposed on at least one of the boundaries of the first to third sub-pixels PX1, PX2, and PX3, but the embodiments of the present disclosure are not limited thereto. The bank 154 and the spacer 155 may be formed of the same material and formed simultaneously through a halftone mask, but the embodiments of the present disclosure are not limited thereto.

The organic layer 152 may be disposed on the first electrode 151, the bank 154, and the spacer 155. The second electrode 153 may be disposed on the organic layer 152.

The encapsulation part 170 may be disposed on the second electrode 153. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic insulation material layers and one or more organic material layers. For example, the first encapsulation layer 171 and the third encapsulation layer 173 may include an inorganic insulation material, and the second encapsulation layer 172 may include an organic material, but the embodiments of the present disclosure are not limited thereto.

The touch part 180 may be disposed on the encapsulation part 170. The touch part 180 may include the touch buffer layer 181, a first touch conductive layer, the first touch insulating layer 183, the second touch insulating layer 184, and a second touch conductive layer. In some embodiments, one or more touch organic layers may be further disposed on the second touch conductive layer, but the embodiments of the present disclosure are not limited thereto.

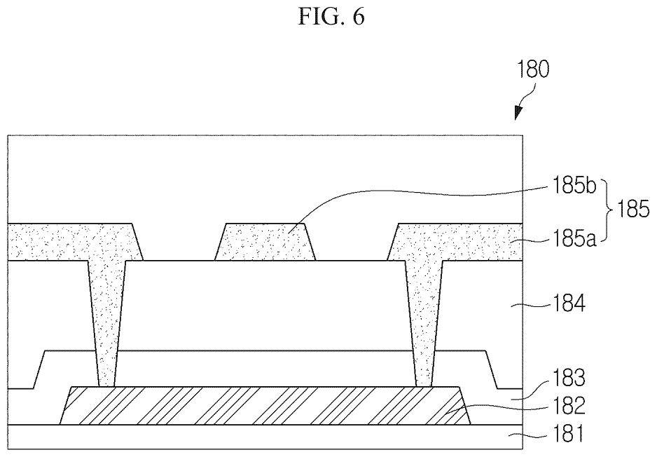

FIG. 6 is a cross-sectional view of a touch part according to FIG. 3.

Referring to FIGS. 3 and 6, the touch buffer layer 181 may be disposed on the encapsulation part 170. For example, a touch buffer layer 181 may be disposed on the third encapsulation layer 173. The touch buffer layer 181 may be formed of the same material as the buffer layer 102, but the embodiments of the present disclosure are not limited thereto.

The first touch conductive layer may be disposed on the touch buffer layer 181. The first touch conductive layer may include a bridge electrode 182. The bridge electrode 182 and a sensor electrode 185 to be described below may be disposed at each of the boundaries between adjacent sub-pixels PX1, PX2, and PX3. For example, the bridge electrode 182 and the sensor electrode 185 may be disposed in the non-light-emitting areas NEA1, NEA2, and NEA3. The bridge electrode 182 and the sensor electrode 185 may overlap the black matrix BM to be described below in the thickness direction. The black matrix BM may cover the bridge electrode 182 and the sensor electrode 185. Accordingly, the bridge electrode 182 and the sensor electrode 185 can be prevented from being visible from the outside.

The first touch insulating layer 183 and the second touch insulating layer 184 disposed on the first touch insulating layer 183 may be disposed on the first touch conductive layer. The first touch insulating layer 183 and the second touch insulating layer 184 disposed on the first touch insulating layer 183 can prevent a short circuit between the first touch conductive layer and the second touch conductive layer. The first touch insulating layer 183 may be formed of silicon oxide (SiOₓ), silicon nitride (SiNₓ), or multiple layers thereof, but the embodiments of the present disclosure are not limited thereto. The second touch insulating layer 184 may include an organic insulation material, but the embodiments of the present disclosure are not limited thereto, and the second touch insulating layer 184 may include the same material as the first touch insulating layer 183.

The second touch conductive layer may be disposed on the second touch insulating layer 184. The second touch conductive layer may include a first sensor electrode 185a and a second sensor electrode 185b. The sensor electrode 185 may include the first sensor electrode 185a extending in the first direction DR1 (see FIG. 1) and the second sensor electrode 185b extending in the second direction DR2 (see FIG. 1) different from the first direction DR1.

The bridge electrode 182 may be electrically connected to the first sensor electrode 185a through a contact hole formed in the first touch insulating layer 183 and the second touch insulating layer 184. For example, the first sensor electrode 185a and the bridge electrode 182 may extend in the first direction DR1 (see FIG. 1).

The sensor electrode 185 and the bridge electrode 182 may include a metallic material. For example, the first touch conductive layer 182 may be formed of titanium (Ti), nickel (Ni), aluminum (Al), or an alloy thereof and formed of a triple layer, such as titanium (Ti)/aluminum (Al)/titanium (Ti), but the embodiments of the present disclosure are not limited thereto.

Referring back to FIG. 3, the filter insulating layer 114 may be disposed on the second touch conductive layer. The filter insulating layer 114 may be formed of an inorganic insulation material, such as silicon nitride (SiNₓ) or silicon oxide (SiOₓ), but the embodiments of the present disclosure are not limited thereto.

The black matrix BM may be disposed on the filter insulating layer 114. The black matrix BM may include a black-based material. For example, the black matrix BM may include a light-blocking material or a light-absorbing material. For example, the black matrix BM may be formed of a material including a black pigment, a black dye, etc. The black matrix BM may cover the bridge electrode 182 and the sensor electrode 185. Accordingly, the bridge electrode 182 and the sensor electrode 185 can be prevented from being visible from the outside. For example, a width of the black matrix BM may be smaller than a width of the bank 154.

For example, spacing distances between an end of the black matrix BM and boundaries between the light-emitting areas EA1, EA2, and EA3 and the non-light-emitting areas NEA1, NEA2, and NEA3 may be longer than spacing distances between an end of the bank 154 and the boundaries between the light-emitting areas EA1, EA2, and EA3 and the non-light-emitting areas NEA1, NEA2, and NEA3. The end of the bank 154 may be aligned with the boundaries between the light-emitting areas EA1, EA2, and EA3 and the non-light-emitting areas NEA1, NEA2, and NEA3, but the embodiments of the present disclosure are not limited thereto. In the display panel 100 according to one embodiment, since the bank 154 may include a black-based material and the spacing distances between the end of the black matrix BM and the boundaries between the light-emitting areas EA1, EA2, and EA3 and the non-light-emitting areas NEA1, NEA2, and NEA3 may be longer than the spacing distances between the end of the bank 154 and the boundaries between the light-emitting areas EA1, EA2, and EA3 and the non-light-emitting areas NEA1, NEA2, and NEA3, light emitted from the light-emitting areas EA1, EA2, and EA3 may be emitted upward with a wider viewing angle as much as the spacing spaces between the end of the black matrix BM and the boundaries between the light-emitting areas EA1, EA2, and EA3 and the non-light-emitting areas NEA1, NEA2, and NEA3. Accordingly, it is possible to prevent a reduction in intensity of luminance according to a viewing angle. However, when the spacing distances between the end of the black matrix BM and the boundaries between the light-emitting areas EA1, EA2, and EA3 and the non-light-emitting areas NEA1, NEA2, and NEA3 may be longer than the spacing distances between the end of the bank 154 and the boundaries between the light-emitting areas EA1, EA2, and EA3 and the non-light-emitting areas NEA1, NEA2, and NEA3 and the bank 154 is formed of only a transparent material, externally incident light may be reflected by the bank 154, resulting in visible ring-shaped spots. However, in the display panel 100 according to one embodiment, the externally incident light may be absorbed or shielded by the bank 154 including a black-based material, thereby preventing the occurrence of the ring-shaped spots.

The color filters 191, 192, and 193 may be disposed on the black matrix BM. The color filters 191, 192, and 193 may be disposed on the first to third sub-pixels PX1, PX2, and PX3, respectively, and may block specific colors from light emitted from the light-emitting area EA1, EA2, and EA3 of the sub-pixels PX1, PX2, and PX3. A first color filter 191 may be provided to block light of other colors not including red (R) light. In this case, the first color filter 191 may be provided as a red color filter. A second color filter 192 may be provided to block light of other colors not including green (G) light. In this case, a second color filter 192 may be provided as a green color filter. A third color filter 193 provided in the third sub-pixel PX3 may be provided to block light of other colors not including blue (B) light. In this case, the third color filter 193 may be provided as a blue color filter. However, the embodiments of the present disclosure are not limited thereto.

For example, each color filter 191, 192, or 193 may come into direct contact with side and upper surfaces of the black matrix BM. For example, each color filter 191, 192, or 193 may be spaced apart from the boundaries of adjacent sub-pixels PX1, PX2, and PX3, but the embodiments of the present disclosure are not limited thereto, and the color filters 191, 192, and 193 may overlap each other in the thickness direction.

The planarization layer OC may be disposed on the color filters 191, 192, and 193. The planarization layer OC may serve to planarize a step formed by the color filters 191, 192, and 193. For example, the planarization layer OC may include an organic insulation material.

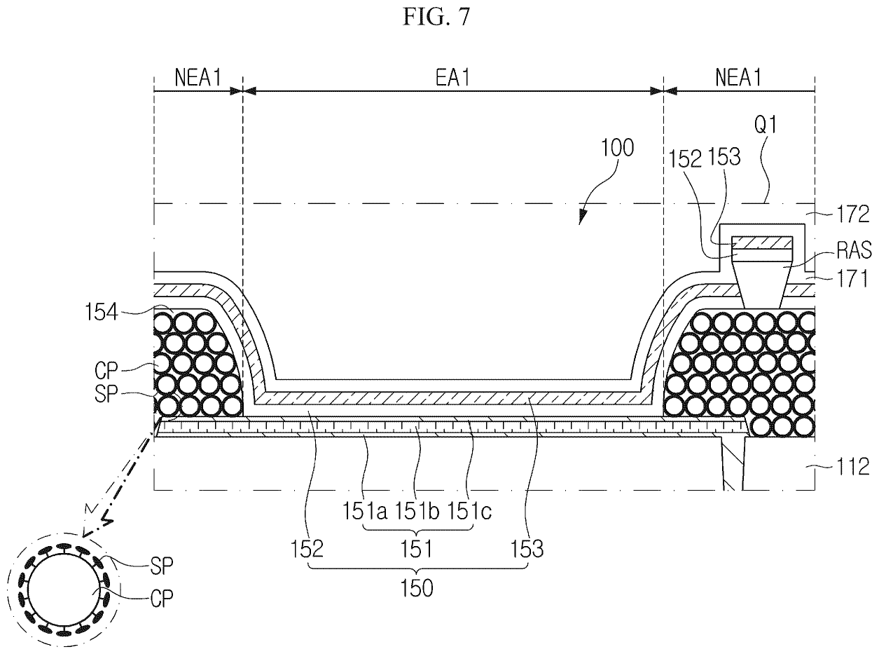

FIG. 7 is an enlarged cross-sectional view of area Q1 in FIG. 3.

Referring to FIGS. 3 and 7, the first electrode 151 according to one embodiment may have a stacked structure of a plurality of conductive layers. For example, the first electrode 151 may include a first conductive layer 151a, a second conductive layer 151b on the first conductive layer 151a, and a third conductive layer 151c on the second conductive layer 151b. For example, the reactivity of the first conductive layer 151a, the third conductive layer 151c, and the second conductive layer 151b may be different. For example, the reactivity of the first conductive layer 151a and the third conductive layer 151c may be lower than the reactivity of the second conductive layer 151b. In the present disclosure, the reactivity may be ion reactivity and may be, for example, the reactivity of ions of a material forming the third conductive layer 151c with ions of a surrounding material. For example, when the bank includes a black-based pigment, an additive may be included in the bank. The additive may be volatilized to the outside of the bank. The volatilized additive may have an ionic form, and the volatilized additive may include chlorine ions, ozone ions, sulfur ions, bromine ions, etc.

Furthermore, during the manufacturing process of the display panel 100, the third conductive layer 151c disposed on an uppermost portion of the first electrode 151 may include a pin hole due to physical stimulation. As described above, since the reactivity of the second conductive layer 151b is relatively high, the ions of the material forming the second conductive layer 151b (e.g., silver ions) and the ions of the volatilized additive may react with each other within the pin hole, thereby generating a salt. The generated salt may deteriorate a function of the reflective electrode or the anode electrode of the first electrode 151, thereby lowering the intensity of luminance of the display panel 100.

However, according to the display panel 100 according to one embodiment, the bank 154 may be composed of a shell SP including a black-based dye that does not include an additive, and core materials CP with which a plurality of shells SP are combined. Accordingly, it is possible to prevent the intensity of luminance of the display panel 100 from being lowered by the volatilized additive. More specifically, the plurality of shells SP may be combined with the plurality of core materials CP, respectively. The core material CP and the shell SP may be combined to form a core-shell structure. The core material CP may include a transparent conductive material or a metal oxide. The transparent conductive material may include indium tin oxide (ITO), indium tin zinc oxide (ITZO), indium gallium zinc oxide (IGZO), etc., but the embodiments of the present disclosure are not limited thereto. The metal oxide may include TiO₂, etc., but the embodiments of the present disclosure are not limited thereto. The core material CP may include a material having a large surface area to form the core-shell structure with the plurality of shells SP. For example, the core material CP may be formed of titanium dioxide (TiO₂) having a large surface area, but the embodiments of the present disclosure are not limited thereto. The shell SP may include a black-based dye. The core material CP and the black-based dye (or shell SP) may not react with the first electrode 151. For example, the core material CP and the black-based dye (or shell SP) may not chemically react with the second conductive layer 151b of the first electrode 151. For example, the core material CP and the black-based dye (or shell SP) may not react with silver (Ag).

The bank 154 according to one embodiment may have the plurality of shells SP combined with the plurality of core materials CP, thereby securing the structural stability of the bank 154 without additives.

In addition, the bank 154 may form the core-shell structure with the black-based dye (or shell SP) having a large surface area so that more shells SP are combined with one core material CP or coated on one core material CP, thereby increasing the ratio of the black-based dye within the bank 154 and preventing surface reflection (or external light reflection).

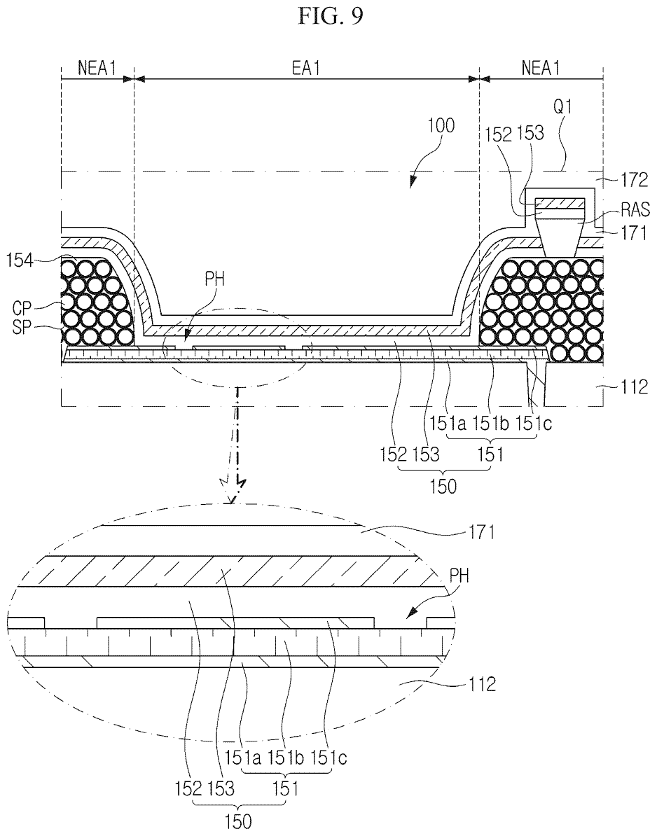

Since the shell SP surrounds an edge of the core material CP, the shell SP may be in direct contact with the upper surface and side surfaces of the second protective layer 112 or the first electrode 151 as illustrated in FIG. 9. The core material CP or the shell SP may be in direct contact with the organic layer 152 disposed thereabove. The core material CP or the shell SP may be in direct contact with the second protective layer 112 or the first electrode 151 disposed thereunder.

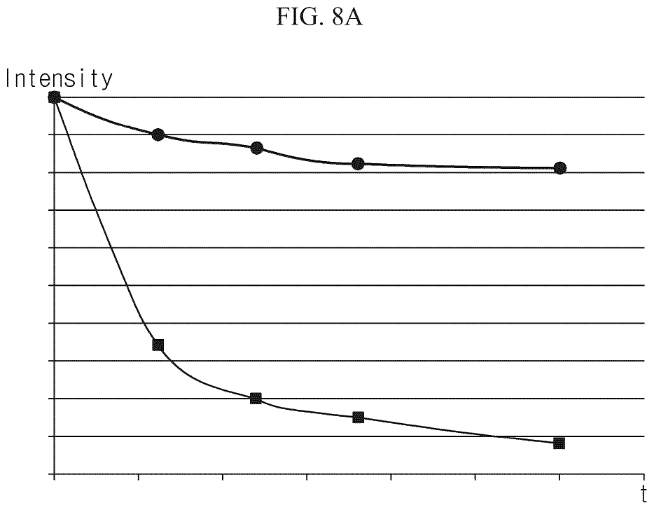

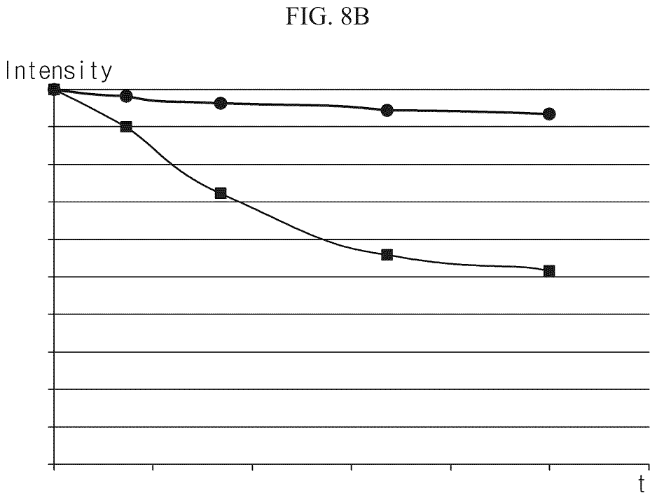

FIG. 8A is a graph illustrating the intensity of luminance loss of the display device in a first environment. FIG. 8B is a graph illustrating the intensity of luminance loss of the display device in a second environment.

FIGS. 8A and 8B illustrate the intensity of luminance of the display device in different environments, respectively. In FIGS. 8A and 8B, horizontal axes represent time (t), and vertical axes represent the intensity of luminance of the display device. The first environment is a harsh environment, for example, a temperature of 110° C., a humidity of 85%, and a pressure of 1.2 atm. The second environment is a high temperature and high humidity environment, for example, a temperature of 110° C. and a humidity of 85%. The bank of the display device applied to the experiment in FIGS. 8A and 8B may include a black-based pigment or an additive. In the first and second environments, the intensity of luminance of the display device can be lowered over time (t). As described above in combination with FIG. 7, this is because, during the manufacturing process of the display panel 100, the pin hole is formed in the third conductive layer 151c at the uppermost portion of the first electrode 151 due to physical stimulation, and since the reactivity of the second conductive layer 151b is relatively high, the ions of the material forming the second conductive layer 151b (e.g., silver ions) and the ions of the volatilized additive react with each other in the pin hole, thereby generating a salt.

However, according to the display device according to one embodiment, in the display panel 100 according to one embodiment, the bank 154 may be composed of the shell SP including a black-based dye that does not include an additive and the core material CP with which the plurality of shells SP are combined. Accordingly, even when the pin hole is generated in the first electrode 151 having the stacked structure of conductive layers during the manufacturing process of the display panel, the bank does not chemically react with the component of the first electrode 151 (the conductive layer constituting the first electrode, for example, 151b), and thus it is possible to prevent the intensity of luminance of the display panel from being lowered.

FIG. 9 is a cross-sectional view illustrating the effect by a bank according to one embodiment.

Referring to FIG. 9, as described above in combination with FIGS. 7 and 8A-8B, the first electrode 151 may include a plurality of pin holes PH. In particular, the third conductive layer 151c of a first electrode 151 may include the plurality of pin holes PH, and the pin holes PH may pass through a third conductive layer 151c in the thickness direction. In the pin hole PH, the organic layer 152 may be in direct contact with the second conductive layer 151b.

According to one embodiment, since the bank 154 is composed of the shell SP including a black-based dye that does not include an additive and the core material CP with which the plurality of shells SP are combined, the bank 154 may not include a volatile additive. Accordingly, even when the plurality of pin holes PH are formed in the third conductive layer 151c, the second conductive layer 151b exposed by the pin holes PH can be prevented from chemically reacting with the bank 154 and lowering the intensity of luminance of the display panel.

In addition, since the display panel 100 according to one embodiment does not require a high-temperature process, such as hard baking, it is possible to prevent damage to the elements on the substrate.

Hereinafter, a display device according to other embodiments will be described. In the following embodiments, the detailed description of the components having described in FIGS. 1 to 9 will be omitted, or the overlapping descriptions thereof will be omitted.

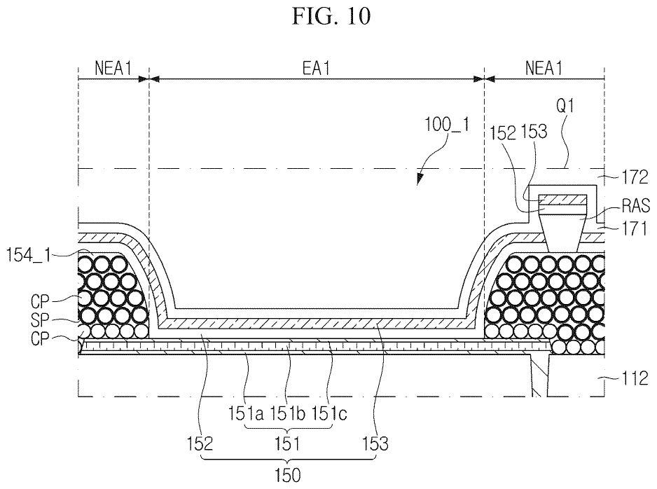

FIG. 10 is a cross-sectional view of a display device according to another embodiment.

Referring to FIG. 10, a display panel 100_1 of the display device according to the present embodiment differs from the display panel 100 according to FIG. 7 in that the shell SP may not be combined to the core material CP adjacent to the first electrode 151 or the second protective layer 112.

More specifically, the core material CP may be in direct contact with the first electrode 151 or the second protective layer 112.

A bank 154_1 according to the present embodiment may be formed because the black-based dye (or shell) of the ink does not reach the core material CP at a lowermost end thereof during the process of coating the core materials CP on the first non-emitting area NEA1 with ink.

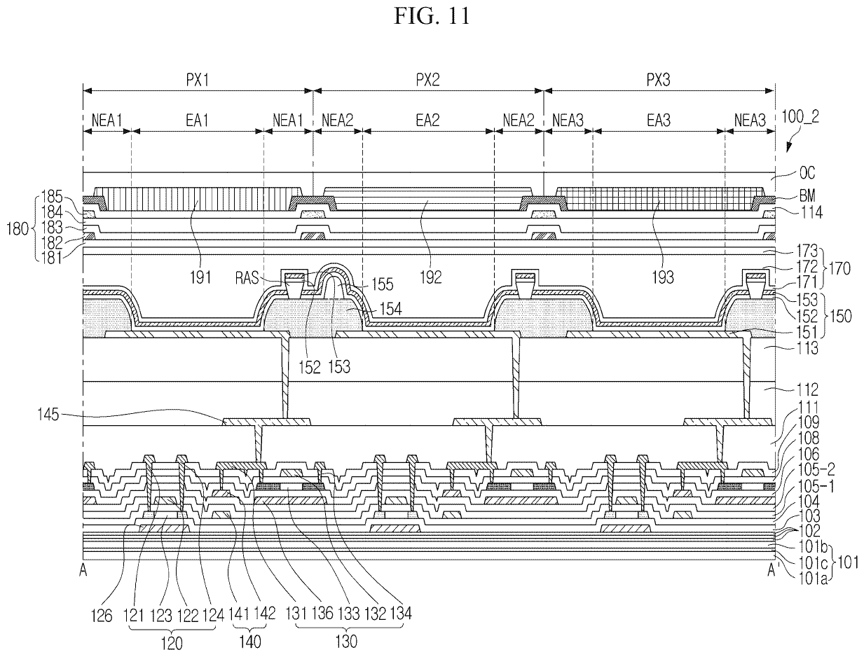

FIG. 11 is a cross-sectional view of a display device according to still another embodiment.

Referring to FIG. 11, a display panel 100_2 of the display device according to the present embodiment differs from the display panel 100 according to FIG. 3 in that it may further include a third protective layer 113 on the second protective layer 112.

More specifically, the display panel 100_2 according to the present embodiment may further include the third protective layer 113 between the second protective layer 112 and the first electrode 151. A material of the third protective layer 113 may include at least one of materials exemplified as the material of the second protective layer 112, but the embodiments of the present disclosure are not limited thereto.

Since the remaining parts have been described above in combination with FIG. 3, the detailed descriptions thereof will be omitted.

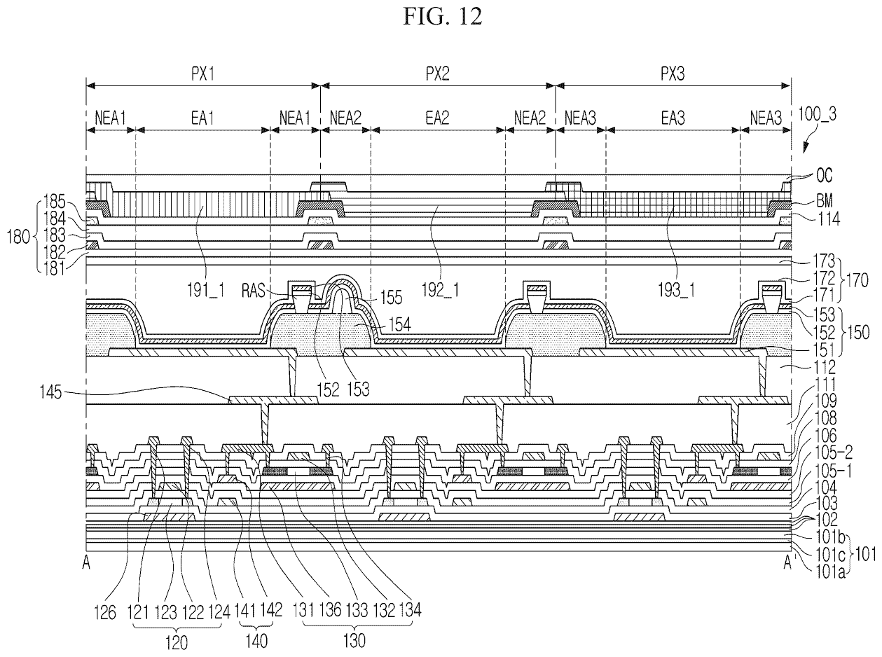

FIG. 12 is a cross-sectional view of a display device according to yet another embodiment.

Referring to FIG. 12, color filters 191_1, 192_1, and 193_1 of a display panel 100_3 of the display device according to the present embodiment differ from the display panel 100 according to FIG. 3 in that they may overlap each other in the non-light-emitting areas NEA1, NEA2, and NEA3.

FIG. 12 illustrates that a second color filter 192_1 is located at the top, and a first color filter 191_1 is located under the second color filter 192_1 in a non-light-emitting area NEA1 adjacent to non-light-emitting area NEA2, and a third color filter 193_1 is located at the top, and the second color filter 192_1 is located under the third color filter 193_1 in a non-light-emitting area NEA3 adjacent to non-light-emitting area NEA2, but the stacking order of the color filter 191_1, 192_1, and 193_1 in the non-light-emitting areas NEA1, NEA2, and NEA3 may vary according to a process order.

Since the remaining parts have been described above in combination with FIG. 3, the detailed descriptions thereof will be omitted.

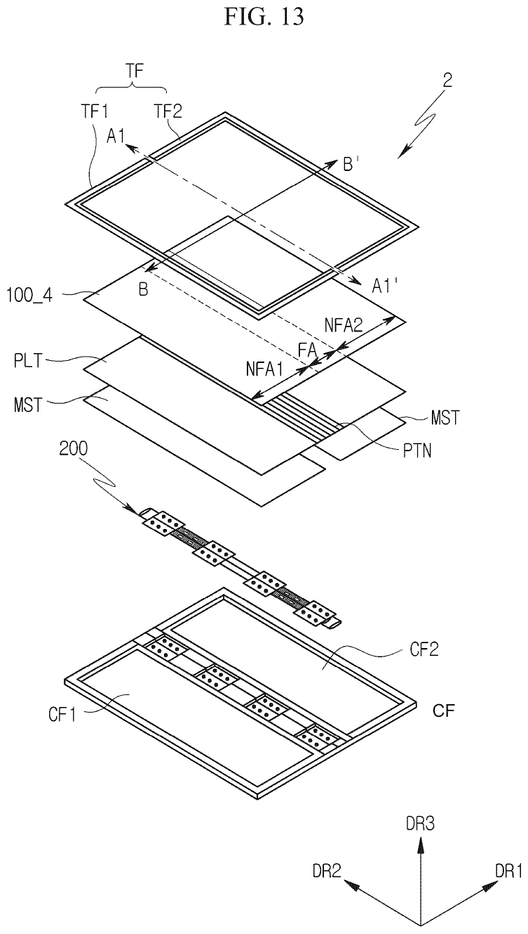

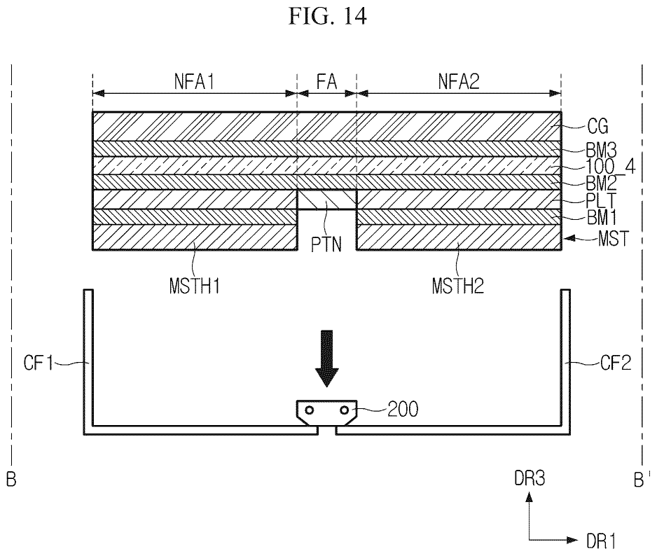

FIG. 13 is a perspective view of a display device according to still another embodiment. FIG. 14 is a cross-sectional view along line B-B′ in FIG. 13.

Referring to FIGS. 13 and 14, a display device 2 according to the present embodiment differs from the display device 1 according to FIG. 1 in that it is a foldable display device.

In the present disclosure, a folding axis A1 along which the display device 2 is folded may be the same as the second direction DR2.

A top frame TF is disposed at the top of the display device 2. With respect to the folding axis A1, the top frame TF includes a first top frame TF1 disposed at one side and a second top frame TF2 disposed at the other side. The top frame TF may be disposed to cover an edge of the display panel 100_4. The top frame TF can protect the display panel 100_4 from an external impact. The top frame TF may form a bezel of the display device 2.

A cover layer CG may be disposed under the top frame TF. The cover layer CG may be disposed above the display panel 100_4.

The cover layer CG may be disposed above the display panel 100_4 to protect members disposed under the cover layer CG from the external impact.

A panel assembly is disposed under the cover layer CG. The panel assembly includes the display panel 100_4 and a plate PLT. The display panel 100_4 may be substantially the same as one of the above display panels 100, 100_1, 100_2, and 100_3.

The plate PLT may include various plates disposed under the display panel 100_4 to support the display panel 100_4. For example, one or more plates may include a back plate for supporting the display panel 100_4, a top plate disposed under the back plate and formed of a stainless steel (SUS) material, a bottom plate disposed under the top plate, having a pattern formed on a folding portion, and formed of a SUS material, a heat-dissipation plate that performs a heat-dissipation function, a middle plate for covering a non-planarized flat surface caused by various components of a hinge assembly, etc.

A slit pattern PTN may be formed in the plate PLT. The slit pattern PTN may be formed at a location corresponding to a folding area FA of the display panel 100_4. The slit pattern PTN may be a slit-shaped etched portion formed in the plate PLT. For example, the plate PLT may be formed of a metal, such as a SUS material, but the strong nature of the metal may cause problems in folding or unfolding the plate PLT. The slit pattern PTN may supplement the flexibility of the plate PLT.

A middle plate MST is disposed under the panel assembly. The middle plate MST supports components disposed thereabove. In addition, a hinge assembly 200 and a cover frame CF are disposed downward from the middle plate MST, and their upper surfaces may be uneven. The middle plate MST may flatten a non-planarized lower surface. The middle plate MST may be formed of a material, such as plastic, polyimide, metal, etc., to increase the rigidity of the display device 2. For example, the middle plate MST may include aluminum or SUS, but is not limited thereto.

The middle plate MST may include a first middle plate portion MSTH1 disposed in a first unfolding area NFA1, and a second middle plate portion MSTH2 disposed in a second unfolding area NFA2.

The hinge assembly 200 is disposed under the panel assembly. The hinge assembly 200 is disposed under the folding area FA. The hinge assembly 200 may have a shape extending along the folding axis A1. The hinge assembly 200 may perform a folding motion in which one side and the other side rotate about the folding axis A1.

The cover frame CF is disposed under the hinge assembly 200. An accommodation groove in which a part of the hinge assembly 200 may be seated may be formed in an upper surface of the cover frame CF. With respect to the folding axis A1, the cover frame CF includes a first cover frame CF1 disposed at one side and a second cover frame CF2 disposed at the other side. The cover frame CF may be a housing for defining the side and rear surfaces of the display device 2. The cover frame CF may protect the display device 2 from an external impact. The cover frame CF may be coupled to the hinge assembly 200. Folding and unfolding of the display device 2 may be implemented according to the rotation of the cover frames CF1 and CF2.

Coupling members BM1, BM2, and BM3 for coupling the adjacent members MST, PLT, PTN, and CG may be further disposed between the adjacent members. In each of the unfolding areas NFA1 and NFA2, a first coupling member BM1 may couple the middle plate portions MSTH1 and MSTH2 to the plate PLT disposed above the middle plate portions MSTH1 and MSTH2, a second coupling member BM2 may couple the plates PLT and PTN to the display panel 100_4 disposed above the plates PLT and PTN, and a third coupling member BM3 may couple the display panel 100_4 to the cover layer CG.

The plate PLT and the middle plate MST that are coupled may be seated on the cover frames CF1 and CF2. The display device 2 may perform folding and unfolding operations by the hinge assembly 200 disposed on the cover frames CF1 and CF2.

Since the display panel 100_4 has been described above, the detailed descriptions thereof will be omitted below.

A display device according to various embodiments of the present disclosure may be described as follows.

According to various embodiments of the present disclosure, there is provided a display device including a substrate, a display area, a non-display area outside the display area, a first electrode disposed on the substrate, a bank overlapping a periphery of an upper surface of the first electrode, an organic layer on the first electrode and the bank; and a second electrode on the organic layer, in which the bank includes core materials and black-based dyes combined with the core materials.

In the display device according to various embodiments of the present disclosure, the core material may include a transparent conductive material or a metal oxide.

In the display device according to various embodiments of the present disclosure, a black-based dye of the black-based dyes or a core material of the core materials may be in direct contact with the organic layer.

The display device according to various embodiments of the present disclosure may further include a first transistor between the substrate and the first electrode, and a second transistor between the first transistor and the first electrode.

In the display device according to various embodiments of the present disclosure, a semiconductor layer of the first transistor may include a polysilicon, and a semiconductor layer of the second transistor may include an oxide.

The display device according to various embodiments of the present disclosure may further include a first protective layer disposed between the second transistor and the first electrode, and a second protective layer between the first protective layer and the first electrode.

The display device according to various embodiments of the present disclosure may further include a connection electrode disposed between the second protective layer and the first electrode and connecting the first electrode to the second transistor.

In the display device according to various embodiments of the present disclosure, a black-based dye of the black-based dyes or a core material of the core materials may be in direct contact with the second protective layer.

In the display device according to various embodiments of the present disclosure, the bank may be disposed on the first electrode and located at a boundary between adjacent sub-pixels.

In the display device according to various embodiments of the present disclosure, the plurality of sub-pixels may include a first sub-pixel, a second sub-pixel, and a third sub-pixel, and the organic layer may be disposed across the first sub-pixel to the third sub-pixel.

In the display device according to various embodiments of the present disclosure, the organic layer may include a first light-emitting layer on the first sub-pixel, a second light-emitting layer on the second sub-pixel, and a third light-emitting layer on the third sub-pixel.

In the display device according to various embodiments of the present disclosure, in each sub-pixel, each of the first light-emitting layer, the second light-emitting layer, and the third light-emitting layer may be stacked in two or more layers.

The display device according to various embodiments of the present disclosure may further include a color filter on the second electrode and a black matrix located at a boundary between adjacent sub-pixels between the second electrode and the color filter, in which a width of the black matrix may be smaller than a width of the bank.

In the display device according to various embodiments of the present disclosure, an end of the black matrix may be closer to a boundary between the sub-pixels than an end of the bank.

The display device according to various embodiments of the present disclosure may further include a touch part between the second electrode and the color filter, in which the touch part may include a bridge electrode, and a sensor electrode on the bridge electrode, and the black matrix may overlap the bridge electrode and the sensor electrode.

According to various embodiments of the present disclosure, there is provided a display device including a substrate, a display area including a plurality of sub-pixels, a non-display area outside the display area, a first electrode disposed in each of the sub-pixels on the substrate and including a first conductive layer, a second conductive layer on the first conductive layer, and a third conductive layer on the second conductive layer, a bank overlapping a periphery of an upper surface of the first electrode, an organic layer on the first electrode and the bank, and a second electrode on the organic layer, in which the third conductive layer includes a hole passing therethrough in a thickness direction, and the bank includes black-based dyes.

In the display device according to various embodiments of the present disclosure, the bank may further include core materials, and the core materials and the black-based dyes may form a core-shell structure.

In the display device according to various embodiments of the present disclosure, reactivity of the second conductive layer may be higher than reactivity of the third conductive layer.

In the display device according to various embodiments of the present disclosure, the first conductive layer and the third conductive layer may include indium tin oxide (ITO), and the second conductive layer may include silver (Ag).

In the display device according to various embodiments of the present disclosure, the organic layer may be in direct contact with the second conductive layer in the hole.

In the display device according to the embodiments, since the bank does not include the additive, even when the pin hole is generated in the first electrode having the stacked structure of the conductive layers during the manufacturing process of the display panel, the bank does not chemically react with the component of the first electrode (the conductive layer constituting the first electrode), and thus it is possible to prevent the intensity of luminance of the display panel from being lowered.

In the display device according to the embodiments, the dye of the bank may be a black dye, and the black dye may serve as the shell so that the bank may have the core-shell structure in which the core and the black dye are combined, thereby having structural stability.

In the display device according to the embodiments, since the bank has the core-shell structure, more black dyes can be combined (or coated) on one core to increase the ratio of black dye within the bank, thereby preventing surface reflection (or external light reflection).

According to the embodiments of the present disclosure, since the high-temperature process, such as hard baking, is not required, it is possible to prevent damage to the elements on the substrate.

According to the embodiments of the present disclosure, it is possible to provide the low-reflection display device capable of preventing surface reflection of external light, thereby achieving low power.

According to the embodiments of the present disclosure, by omitting the polarizing unit, the display device can have improved flexibility and can be applied to a foldable product in which a display area is folded. However, effects obtainable from the present disclosure are not limited to the above-described effects, and other effects that are not mentioned will be able to be clearly understood by those skilled in the art to which the present disclosure pertains based on the following description.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Accordingly, it should be understood that the above-described embodiments are illustrative and not restrictive in all respects. In addition, the scope of the present disclosure is defined by the claims to be described below rather than the detailed description. In addition, the meaning and scope of the claims and all changed or modified forms derived from the equivalent concept should be construed as being included in the scope of the present disclosure.

What is claimed is:

1. A display device, comprising:
a substrate;
a display area and a non-display area outside the display area;
a first electrode disposed on the substrate;
a bank overlapping a periphery of an upper surface of the first electrode;
an organic layer disposed on the first electrode and the bank; and
a second electrode on the organic layer,
wherein the bank includes core materials and black-based dyes combined with the core materials.

2. The display device of claim 1, wherein the core materials include a transparent conductive material or a metal oxide.

3. The display device of claim 1, wherein a black-based dye of the black-based dyes or a core material of the core materials is in direct contact with the organic layer.

4. The display device of claim 1, further comprising: a first transistor between the substrate and the first electrode; and a second transistor between the first transistor and the first electrode.

5. The display device of claim 4, wherein a semiconductor layer of the first transistor includes a polysilicon, and a semiconductor layer of the second transistor includes an oxide.

6. The display device of claim 4, further comprising: a first protective layer disposed between the second transistor and the first electrode; and a second protective layer between the first protective layer and the first electrode.

7. The display device of claim 6, further comprising a connection electrode disposed between the second protective layer and the first electrode and connecting the first electrode to the second transistor.

8. The display device of claim 6, wherein a black-based dye of the black-based dyes or a core material of the core materials is in direct contact with the second protective layer.

9. The display device of claim 1, further comprising: a color filter on the second electrode; and a black matrix located at a boundary between adjacent sub-pixels between the second electrode and the color filter, wherein a width of the black matrix is smaller than a width of the bank.

10. The display device of claim 9, wherein an end of the black matrix is closer to the boundary between the adjacent sub-pixels than an end of the bank.

11. The display device of claim 1, wherein the first electrode includes a first conductive layer, a second conductive layer on the first conductive layer, and a third conductive layer on the second conductive layer, and
wherein the third conductive layer includes a hole passing therethrough in a thickness direction.

12. The display device of claim 11, wherein reactivity of the second conductive layer is higher than reactivity of the third conductive layer.

13. The display device of claim 12, wherein the first conductive layer and the third conductive layer include indium tin oxide (ITO), and
wherein the second conductive layer includes silver (Ag).

14. The display device of claim 11, wherein the organic layer is in direct contact with the second conductive layer in the hole.

15. The display device of claim 1, wherein the core materials include a transparent conductive material or a metal oxide, wherein the transparent conductive material includes indium tin oxide (ITO), indium tin zinc oxide (ITZO), or indium gallium zinc oxide (IGZO), and wherein the metal oxide includes titanium dioxide (TiO₂).

16. The display device of claim 1, wherein the core materials and the black-based dyes do not react with the first electrode.

17. The display device of claim 1, wherein the core materials and the black-based dyes do not react with silver (Ag).
